(19) United States
(12) Patent Application Publication
(10) Pub. No.: US 2012/0065919 A1
(43) Pub. Date: Mar. 15, 2012

(54) BUILT-IN SELF-TEST CIRCUIT-BASED RADIATION SENSOR, RADIATION SENSING METHOD AND INTEGRATED CIRCUIT INCORPORATING THE SAME

(75) Inventors: Jeff S. Brown, Fort Collins, CO (US); Jonathan Byrn, Fort Collins, CO (US); Mark F. Turner, Boulder, CO (US)

(73) Assignee: LSI Corporation, Milpitas, CA (US)

(21) Appl. No.: 12/881,839

(22) Filed: Sep. 14, 2010

(51) Int. Cl. G01R 31/3187; G06F 19/00

(52) U.S. Cl. 702/117; 324/750.3

(57) ABSTRACT

A radiation sensor for an integrated circuit (IC), a radiation sensing method and an IC incorporating the sensor or the method. In one embodiment, the radiation sensor includes: (1) a built-in self-test (BIST) controller configured to provide BIST with respect to main IC circuitry of the IC and (2) a radiation sensor controller coupled to the main IC circuitry and the BIST controller and configured to identify temporarily inactive portions of the main IC circuitry and cause the BIST controller to perform at least one BIST with respect to at least one of the portions, the at least one of the portions acting as a radiation target.

### TECHNICAL FIELD

This application is directed, in general, to error detection circuitry and, more specifically, to a built-in self-test circuit (BIST)-based radiation sensor, a radiation sensing method and an integrated circuit (IC) incorporating the sensor or the method.

### BACKGROUND

Background radiation from alpha particles, neutrons and cosmic rays can create “soft errors” by causing momentary upsets (so-called single-event upsets, or SEUs) in data inside an IC. For example, digital complementary metal-oxide semiconductor (CMOS) IC transistors are vulnerable to soft errors when the outputs (e.g., drains) of turned-off transistors are driven to logic values that are opposite the values of the depletion regions of their reverse-biased diffusion-well junctions.

Some SEUs, called single-event transients (SETs), do not affect bit values. Other, more severe SEUs may affect the value of one or more bits. SEUs that affect the value of one bit are called single-bit upsets (SBUs). The rate at which SBUs occur affects the IC's soft error rate (SER) and failure-in-time (FIT) rate. SBUs may go unnoticed if the data is changed back to the correct value before it is stored. However, an SBU may cause an error if the upset data is stored or if the upset directly changes the data contained in a storage element, such as a D flip-flop or a memory cell. Persistent SEUs in control logic or a state machine can cause control errors or force a state-machine into an unwanted state, leading to operational failure in the IC. Decreases in feature sizes and operating voltages have caused the SER of standard logic elements in ICs to rise.

### SUMMARY

One aspect provides a radiation sensor for an IC. In one embodiment, the radiation sensor includes: (1) a BIST controller configured to provide BIST with respect to main IC circuitry of the IC and (2) a radiation sensor controller coupled to the main IC circuitry and the BIST controller and configured to identify temporarily inactive portions of the main IC circuitry and cause the BIST controller to perform at least one BIST with respect to at least one of the portions, the at least one of the portions acting as a radiation target.

Another aspect provides a radiation sensing method for an IC. In one embodiment, the radiation sensing method includes: (1) identifying temporarily inactive circuitry in the IC, (2) initiating BIST with respect to at least some of the temporarily inactive circuitry and (3) providing an indication of the existence of one or more radiation effects.

Yet another aspect provides an IC. In one embodiment, the IC includes: (1) main IC circuitry, (2) a BIST controller configured to provide BIST with respect to the main IC circuitry and (3) a radiation sensor controller coupled to the main IC circuitry and the BIST controller and configured to identify temporarily inactive portions of the main IC circuitry and cause the BIST controller to perform at least one BIST with respect to at least one of the portions, the at least one of the portions acting as a radiation target.

### BRIEF DESCRIPTION

Reference is now made to the following descriptions taken in conjunction with the accompanying drawings, in which:

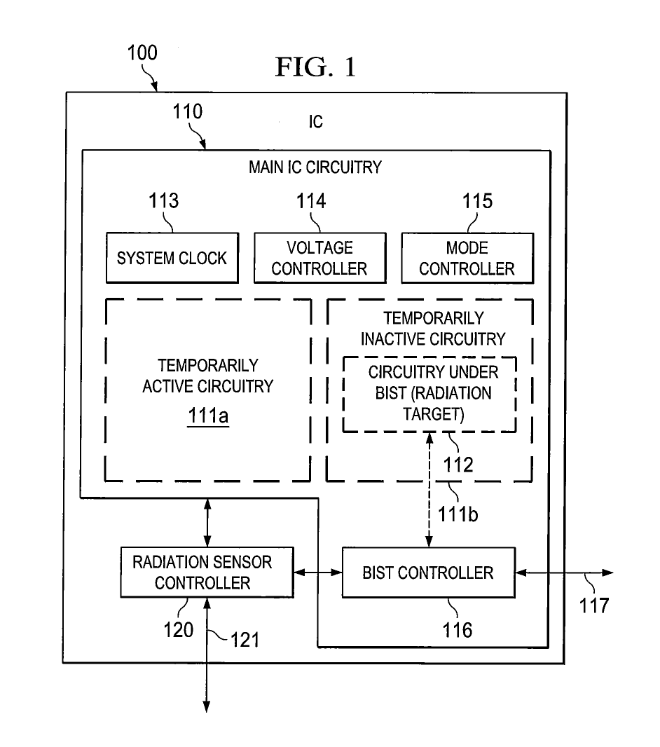

FIG. 1 is a block diagram of one embodiment of an IC containing a radiation sensor or carrying out a radiation sensing method;

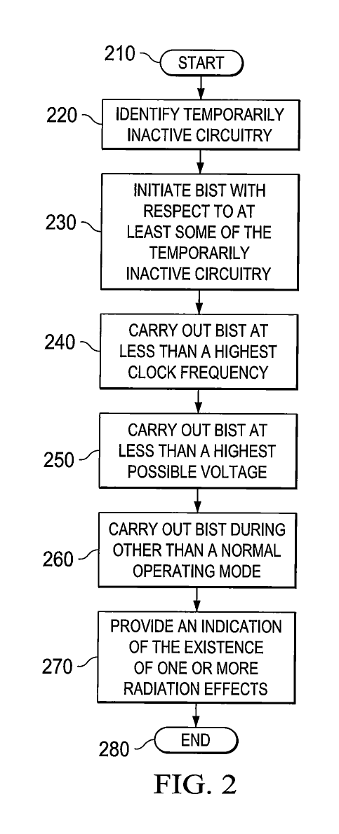

FIG. 2 is a flow diagram of one embodiment of a radiation sensing method; and

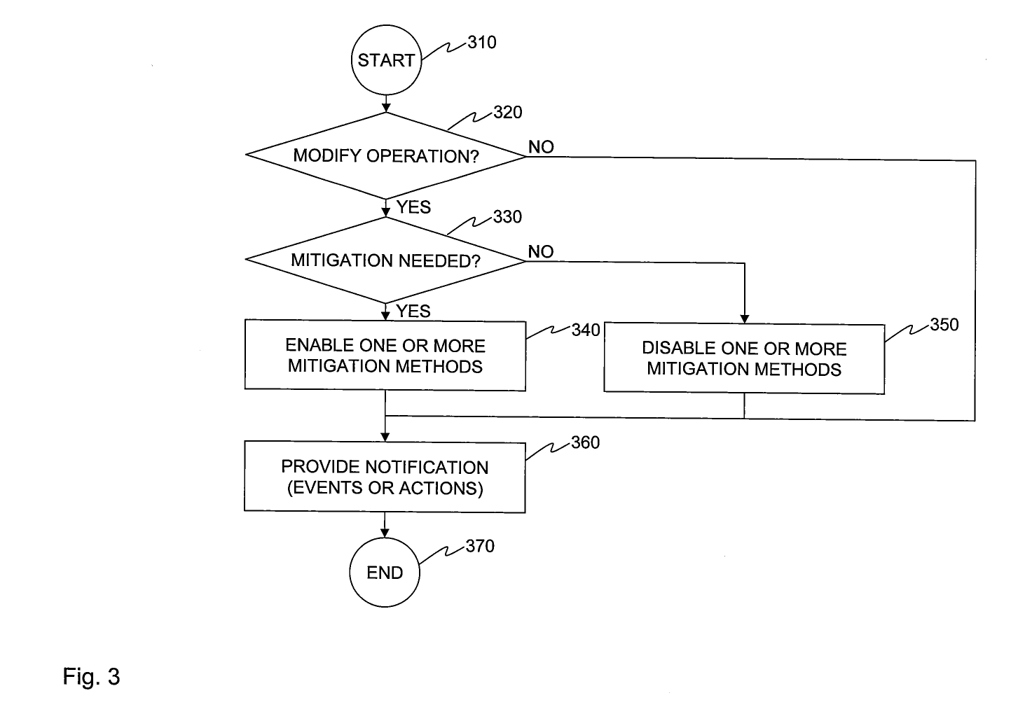

FIG. 3 is a flow diagram of one embodiment of a method of responding to an indication of radiation effects occurring with respect to an IC.

### DETAILED DESCRIPTION

As stated above, persistent SEUs can lead to system failure in the IC, and this problem is expected to intensify as ever-decreasing feature sizes and operating voltages make ICs evermore vulnerable to radiation effects.

One solution is to harden ICs against radiation. In fact, ICs intended for use in high-radiation environments mitigate radiation effects by employing devices having larger features and operating at higher voltages and radiation-tolerant architectures such as redundancy and voting. While these ICs are justified in high-radiation applications, they are disadvantageous in terms of cost, power consumption, speed and size and are therefore inappropriate for the vast majority of commercial applications.

Another solution is to monitor radiation in real-time. To this end, a monitoring circuit called CREST (Circuit for Radiation Effects Self Test) has been proposed for space-based applications (see, e.g., LaBel, et al., “Radiation Test Challenges for Scaled Commercial Memories,” IEEE Transactions on Nuclear Science, vol. 55, no. 4, August 2008). The CREST circuit shifts a known data pattern from a pattern generator through a serial chain of registers (acting as a radiation target) to an error detection circuit. The error detection circuit compares the pattern entering the chain with the pattern leaving the chain. Any difference would indicate at least one SBU.

Monitoring radiation in real-time allows at least an alarm to be provided that radiation is reaching significant levels. However, a radiation monitor can be used to change the IC's operation to mitigate radiation effects. For example, appropriate physical, software or system-level approaches may be applied to deliver an acceptable FIT rate as the probability of soft errors increases. The mitigation itself can even adapt in proportion to the probability of errors. This has significant commercial advantage, because radiation levels change with the physical environment. For example, cosmic radiation levels are related to altitude and can change significantly on airplane flights. Also, free neutrons follow the Earth's magnetic poles, causing neutron flux to vary significantly over the Earth's surface.

Unfortunately, the pattern generator, register chain and error detection circuit that constitute the CREST circuit are distinct from the main circuitry that makes up the remainder of the IC's area. Therefore, the total area of the IC must be larger than necessary to contain just the main IC circuitry; it must be of sufficient area also to include the CREST circuit. “Main IC circuitry,” as that term is used herein, is defined as all circuitry on or in the IC other than any circuitry exclusively dedicated to radiation sensing.

Because the CREST circuit lies outside of the main IC circuitry, it is designed to be relatively small so it minimally increases the total area of the IC. Further, its chain of registers is small compared to its pattern generator and error detection circuit. Each register only has a small number of transistors to provide targets for radiation flux at any given moment. Consequently, little of the CREST circuit's overall area is devoted to radiation-sensitive targets, giving it a poor target-to-circuit-area ratio and a concomitantly poor radiation flux sensitivity.

Introduced herein are various embodiments of a radiation sensor and radiation sensing method and an IC incorporating the sensor or the method. In contrast to the CREST circuit, the radiation sensor incorporates and makes use of portions of the main IC circuitry. The radiation sensor introduced herein is based in part on the recognition that existing main IC circuitry may be temporarily inactive and therefore potentially available to provide a radiation sensing function. As those skilled in the art are aware, many ICs do not employ all of their circuitry at all times. For example, certain processor resources such as floating-point circuitry or multipliers may go unused for short times and may therefore be temporarily available to serve as a radiation target. Also, memories are rarely entirely full; portions of memories are almost always unused (unallocated) and may therefore be temporarily available to serve as a radiation target. The radiation sensor and radiation sensing method may be embodied in any digital cell library and process technology.

Further, many ICs already include a BIST controller to perform “self-testing” on circuitry following manufacture, delivery, installation or startup or during use. Those skilled in the pertinent art are familiar with BIST functions and techniques, including boundary scanning with test vectors. The radiation sensor introduced herein is based in part on the recognition that the radiation sensor or radiation sensing method may employ a BIST controller if it is present and otherwise unused to test the radiation target and thereby provide a radiation sensing function. Therefore, a BIST controller may provide test vectors to boundaries of temporarily inactive circuitry. Those test vectors may be retrieved and compared to yield an indication of the magnitude of radiation effects.

In one embodiment, the radiation sensor employs at least a portion of temporarily inactive circuitry that is a part of the main IC circuitry as a radiation target. Accordingly, the radiation sensor includes a radiation sensor controller configured to identify portions of the main IC circuitry that are temporarily inactive as candidates for the radiation target. Those portions may be logic, memory or combinations of logic and memory. In one embodiment, the radiation sensor controller is further configured to provide an alarm or other indication that one or more radiation effects have been sensed. In a more specific embodiment, the radiation sensor controller is further configured to provide an indication of the intensity of the radiation effect, perhaps in quantitative terms.

In one embodiment, the radiation sensor controller lies wholly outside of the main IC circuitry. In another embodiment, the radiation sensor controller incorporates at least some main IC circuitry and therefore is, by definition, at least partially within the main IC circuitry.

In one embodiment, the radiation sensor employs a BIST controller that is part of the main IC circuitry to test the radiation target to detect radiation effects. In an alternative embodiment, the radiation sensor employs a BIST controller that at least partially lies outside of the main IC circuitry to test the radiation target.

In one embodiment, the BIST controller employs a clock signal to test the radiation target that has a frequency less than the highest clock frequency that may be employed for temporarily active circuitry. In a more specific embodiment, the reduced-frequency clock signal is a predetermined fraction of a clock signal that may be employed for the temporarily active circuitry. In a more specific embodiment, the reduced frequency clock signal is less than about 10 Hz. In a still more specific embodiment, the reduced frequency clock signal is about 1 Hz. Normally, higher clock frequencies are preferred for data processing. However, lower clock frequencies are generally preferred for radiation sensing, as data remains in radiation-vulnerable targets for longer periods of time.

In one embodiment, a voltage (often called V_{dd}) is applied to the radiation target that is less than that employed for temporarily active circuitry. In a more specific embodiment, the lower voltage is one of multiple voltage that a voltage controller on the IC may apply to the temporarily active circuitry. In a still more specific embodiment, the lower voltage is the lowest voltage that the voltage controller on the IC may apply to the temporarily active circuitry. As stated above, lower voltages tend to render devices more, typically exponentially more, vulnerable to radiation effects. Therefore, lower voltages are advantageous for driving the portions of the temporarily inactive circuitry that constitute the radiation target.

In one embodiment, the radiation sensor or radiation sensing method function based on the operational modes of the IC. For example, an IC may be capable of operating in various ones of “normal,” “standby” and “sleep” modes. Each of these modes typically employ different clock frequencies and voltages to meet performance or power consumption objectives. In one specific embodiment, the radiation sensor and radiation sensing method do not function in the sleep mode. In another embodiment, the radiation sensor and radiation sensing method employ a particularly sensitive (e.g., large) radiation sensor when the IC is being employed in particularly critical operations.

FIG. 1 is a block diagram of one embodiment of an IC containing a radiation sensor or carrying out a radiation sensing method. An IC 100 is formed of a substrate (not shown) on or in which is located main IC circuitry 110. At any given moment of time, certain of the main IC circuitry 110 is active (employed in carrying out various functions that the IC 100 is designed to perform), and the remainder of the main IC circuitry 110 is inactive. The former is called “temporarily active circuitry” 111a herein, and the latter is called “temporarily inactive circuitry” 110b herein. Broken-line blocks are used to delineate the temporarily active circuitry 111a and temporarily inactive circuitry 110b in FIG. 1 to imply that various portions of the main IC circuitry 110 are likely to vacillate between being active and inactive over time. As will be described more fully, at least some of the temporarily inactive circuitry 111b at a given time will be identified as candidate radiation target circuitry (“circuitry under BIST” 112).

A system clock 113 is configured to provide at least one clock signal of a predetermined frequency to the IC 100. In the illustrated embodiment, the system clock 113 is configured to provide multiple clock signals of predetermined frequencies; clock selection circuitry (not shown) is configured to select between or among the multiple clock signals the clock signal that is to control the IC 100.

A voltage controller 114 is configured to provide power of a predetermined voltage to the IC 100. In the illustrated embodiment, the voltage controller 114 is configured to provide power of multiple predetermined voltages; voltage selection circuitry (not shown) is configured to select between or among the multiple voltages the voltage to be used for the IC 100.

A mode controller 115 is configured to provide place the IC 100 in one of multiple operating modes. In the illustrated embodiment, the mode controller 115 provides three modes: normal, standby and sleep.

A BIST controller 116 is configured to provide BIST with respect to the main IC circuitry 110. In the illustrated embodiment, the BIST controller 116 is part of the main IC circuitry 110. The BIST controller 116 may, for example employ some processor or memory resources found in the main IC circuitry 110. In an alternative embodiment, the BIST controller 116 at least partially lies outside of the main IC circuitry 110 and therefore does not rely on any processor or memory resources of the main IC circuitry 110 for its own operation.

As those skilled in the art understand, self-testing may be carried out following manufacture, delivery, installation or startup or during use of the IC 100. In the illustrated embodiment, the BIST controller 116 is configured to provide at least one test vector to, and shift the test vector through, boundary scan registers (not shown) associated with various inputs and outputs in the main IC circuitry 110. The BIST controller 116 is further configured to cause the main IC circuitry 110 to operate on input provided by the test vector to yield output that is inserted into the test vector. The BIST controller 116 is yet further configured to receive the modified test vector back from the main IC circuitry 110 and compare it to expected test vectors. Any material discrepancies between the modified test vector and expected test vector indicate test failures and possible malfunctions.

In an alternative embodiment, the BIST controller 116 does not employ test vectors per se, but instead evaluates signals or data received from the main IC circuitry 110 to provide an indication of proper operation. Those skilled in the pertinent art understand that the BIST controller 116 may operate in any conventional or later-developed way to test all or a portion of the main IC circuitry 110. In the illustrated embodiment, the BIST controller 116 includes a test access port (TAP) 117 configured to allow external circuitry to provide commands, test data or both to the BIST controller 116 or receive data or test results from the BIST controller 116.

Irrespective of the specific manner in which the BIST controller 116 tests the main IC circuitry, the radiation sensor and radiation sensing method can employ the BIST controller 116 for radiation sensing. Assuming the same circuitry which indicates a malfunction while serving as a radiation target did not do so during earlier testing, it may be assumed that radiation effects are responsible for the malfunction. Accordingly, radiation sensing becomes a matter of determining what portion of the main IC circuitry 110 should be used for radiation sensing (to act as the circuitry under BIST or radiation target 112), then directing the BIST controller 116 to test that circuitry and report back its results.

Accordingly, the radiation sensor includes a radiation sensor controller 120 coupled to the main IC circuitry 110 and the BIST controller 116. In one embodiment, the radiation sensor controller 120 incorporates at least some main IC circuitry and therefore is, by definition, at least partially within the main IC circuitry 110. The BIST controller 116 may, for example employ some processor or memory resources found in the main IC circuitry 110. However, in the illustrated embodiment, the radiation sensor controller 120 lies wholly outside of the main IC circuitry 110 and therefore does not rely on any processor or memory resources of the main IC circuitry 110 for its own operation. The radiation sensor controller 120 may be embodied in hardware, firmware, software or any combination thereof. In the illustrated embodiment, the radiation sensor controller 120 includes a port 121 configured to allow external circuitry to provide commands or data to the radiation sensor controller 120 or receive commands, data or test results from the radiation sensor controller 120.

In the illustrated embodiment, the radiation sensor controller 120 is configured to identify portions of the main IC circuitry 110 that are temporarily inactive. Therefore, the radiation sensor controller 120 is capable of classifying at least some of the main IC circuitry 110 as temporarily inactive circuitry 110b as opposed to temporarily active circuitry 110a. For example, the radiation sensor controller 120 may cause a portion of unallocated memory to be temporarily allocated for radiation testing. If the memory employs error correction codes (ECC), they should advantageously be disabled to decrease the likelihood that radiation effects will be repaired before detection. Multiple memories, or a combination of memories and logic BIST can be used in combination to increase the total sensor area.

As a further example, the radiation sensor controller 120 may monitor a reservation station associated with a processor (not shown) in the main IC circuitry 110 to determine whether certain processor resources (e.g., a floating-point unit or a multiplier) are temporarily inactive. Other logic may be similarly monitored alternatively or additionally. The temporarily allocated memory portion or temporarily inactive processor resources then become candidates for acting as the circuitry under BIST or radiation target 112. The illustrated embodiment of the radiation sensor controller 120 is configured to determine which temporarily inactive circuitry 111b is to be the radiation target 112 and therefore subjected to BIST.

In the illustrated embodiment, the radiation sensor controller 120 is further configured to cause the BIST controller 116 to perform BIST with respect to the circuitry under BIST 112, perhaps as described above. FIG. 1 employs a broken line to couple the BIST controller 116 to the circuitry under BIST 112 to indicate the temporary nature of the BIST that is performed for the purpose of radiation sensing.

As stated above, the BIST controller 120 may employ a clock signal having a relatively low frequency to perform BIST with respect to the radiation target 116. In the illustrated embodiment, the reduced frequency clock signal is about 1 Hz. The BIST clock frequency can be scaled up or down to match the needs of the IC 100 and its environment; if the radiation flux is high or the system is in a particularly sensitive mode, the BIST clock frequency can be sped up, or vice versa. A relatively high radiation flux may be detected by successive BIST evaluations with errors, in which case speeding up the BIST clock frequency until successful error-free BIST evaluations intermingle with failures to deliver the best resolution of the radiation flux. Likewise, if successive BIST evaluations are error-free, or the IC 100 is in a less sensitive or critical mode, the BIST clock frequency can be reduced to conserve power.

In the illustrated embodiment, the radiation sensor controller 120 causes the BIST controller 116 to be run in a loop. In one embodiment, the radiation sensor controller 120 counts and compares failing BIST tests over time. If the radiation sensor controller 120 controls clock frequency (e.g., by selective clock dividing), it can adjust the clock frequency depending on the results of the BIST, e.g., multiple sequential BIST failures may indicate a need to increase the clock frequency to gain better resolution in time, or multiple sequential BIST passes may indicate the opportunity to decrease the clock frequency and thereby reduce power consumption.

Also as stated above, the BIST controller 116 may employ a relatively low voltage for the radiation target during BIST. In the illustrated embodiment, the lower voltage is the lowest nonzero voltage that the voltage controller 114 can generate. Further, the radiation sensor controller 120 may cause the BIST controller 116 to perform BIST only during a particular operating mode, e.g., the sleep mode, of the IC 100.

The BIST controller 116 is configured to provide one or more BIST results to the radiation sensor controller 120. In the illustrated embodiment, the radiation sensor controller 120 then provides radiation sensing results based on the one or more BIST results. In one embodiment, the radiation sensor controller 120 is configured to provide at least an indication of the existence of one or more radiation effects. In another embodiment, the radiation sensor controller 120 is configured to provide a signal (e.g., a number) indicating a magnitude of the radiation effects. The radiation sensor controller 120 may provide the signal via the port 121 or to the main IC circuitry 110.

In response, hardware, firmware, software or any combination thereof extant in the main IC circuitry 110 may respond to the signal by, e.g., modifying the operation of the IC by, e.g., employing more radiation-tolerant hardware, more stringent error-checking-and-correction techniques or more fault-tolerant (e.g., voting) algorithms, increasing voltage or providing an external warning. Those skilled in the pertinent art will find any number of mitigating adaptations suitable for a particular IC or application given the teachings and suggestions herein.

The radiation sensor and radiation sensing method are not limited to application in a monolithic IC. In one embodiment, the IC 100 is an IC of another conventional or later-developed kind, including but not limited to a “flip-chip” or multichip module (MCM) IC. Further, while the embodiments described above are directed to processor or memory resources in the main IC circuitry 110 as examples of temporarily inactive circuits that may be employed as radiation sensors, the invention is not limited by the functions performed by the IC 100. The main IC circuitry 110 may include circuitry of any conventional or later-developed kind or function.

FIG. 2 is a flow diagram of one embodiment of a radiation sensing method. The method begins in a start step 210. In a step 220, temporarily inactive circuitry in the IC is identified. In a step 230, BIST is initiated with respect to at least some of the temporarily inactive circuitry. In a step 240, BIST is carried out at less than highest possible clock frequency. In a step 250, BIST is carried out at less than highest possible voltage. In a step 260, BIST is carried out during other than normal mode. In a step 270, an indication of the existence of one or more radiation effects is provided. The operation of the IC itself may also be modified based, e.g., on the intensity of the radiation effects. In various other embodiments, fewer than all of the steps 240, 250, 260 are carried out. In yet other embodiments, the steps 240, 250, 260 are carried out in orders that are different from the order set forth in FIG. 2. In still other embodiments, radiation sensing is carried out concurrently using different radiation sensors operating under different clock frequencies, voltages or operating modes. The method ends in an end step 280.

As noted above, the operation of the IC itself may be modified based on the sensing of radiation effects. FIG. 3 is a flow diagram of one embodiment of a method of responding to an indication of radiation effects occurring with respect to an IC. The method begins in a start step 310. In a decisional step 320, it is determined whether the operation of the IC should be modified. If it should, it is then determined in a decisional step 330 whether mitigation is needed. If mitigation is needed, one or more mitigation methods (such as those described above) are enabled in a step 340. If mitigation is not needed, one or more mitigation methods that may have been previously enabled are disabled in a step 350. In a step 360, one or more notifications (e.g., events or actions) are provided, e.g., to the main IC circuitry (110 of FIG. 1) or external circuitry via the port (121 of FIG. 1). If the outcome of the decisional step 320 was such that the operation of the IC should not be modified, the step 360 is nonetheless carried out in this embodiment. The method ends in an end step 370.

Those skilled in the art to which this application relates will appreciate that other and further additions, deletions, substitutions and modifications may be made to the described embodiments.

What is claimed is:

1. A radiation sensor for an integrated circuit (IC), comprising:
a built-in self-test (BIST) controller configured to provide BIST with respect to main IC circuitry of said IC; and
a radiation sensor controller coupled to said main IC circuitry and said BIST controller and configured to identify temporarily inactive portions of said main IC circuitry and cause said BIST controller to perform at least one BIST with respect to at least one of said portions, said at least one of said portions acting as a radiation target.

2. The radiation sensor as recited in claim 1 wherein said radiation sensor controller is configured to cause a portion of unallocated memory in said main IC circuitry to be temporarily allocated.

3. The radiation sensor as recited in claim 1 wherein said BIST controller is part of said main IC circuitry.

4. The radiation sensor as recited in claim 1 wherein said radiation sensor lies outside of said main IC circuitry.

5. The radiation sensor as recited in claim 1 wherein said BIST controller employs a clock signal having a frequency less than a highest clock frequency that may be employed for temporarily active circuitry of said IC.

6. The radiation sensor as recited in claim 1 wherein said radiation sensor controller causes said BIST controller to be run in a loop.

7. The radiation sensor as recited in claim 1 wherein a voltage is applied to said radiation target that is less than that employed for temporarily active circuitry of said IC.

8. The radiation sensor as recited in claim 1 wherein said radiation sensor controller functions based on operational modes of said IC.

9. The radiation sensor as recited in claim 1 wherein said radiation sensor controller prompts said IC to modify an operation thereof based on results of said BIST.

10. A radiation sensing method for an integrated circuit (IC), comprising:
identifying temporarily inactive circuitry in said IC;
initiating built-in self-test (BIST) with respect to at least some of said temporarily inactive circuitry; and
providing an indication of the existence of one or more radiation effects.

11. The method as recited in claim 10 wherein said temporarily inactive circuitry is a portion of memory in said IC.

12. The method as recited in claim 10 wherein said initiating is carried out with respect to a BIST controller that is part of main IC circuitry.

13. The method as recited in claim 10 further comprising carrying out said BIST at less than a highest possible clock frequency.

14. The method as recited in claim 10 further comprising carrying out said BIST at less than highest possible voltage.

15. The method as recited in claim 10 further comprising carrying out said BIST during other than normal mode.

16. The method as recited in claim 10 further comprising repeating said initiating.

17. The method as recited in claim 10 further comprising modifying an operation of said IC based on results of said BIST.

18. An integrated circuit (IC), comprising:
main IC circuitry;
a built-in self-test (BIST) controller configured to provide BIST with respect to said main IC circuitry; and
a radiation sensor controller coupled to said main IC circuitry and said BIST controller and configured to identify temporarily inactive portions of said main IC circuitry and cause said BIST controller to perform at least one BIST with respect to at least one of said portions, said at least one of said portions acting as a radiation target.

19. The IC as recited in claim 18 wherein said radiation sensor controller is configured to cause a portion of unallocated memory in said main IC circuitry to be temporarily allocated.

20. The IC as recited in claim 18 wherein said radiation sensor controller prompts said IC to modify an operation thereof based on results of said BIST.
